(19) United States
(12) Patent Application Publication
(10) Pub. No.: US 2015/0099359 A1
(43) Pub. Date: Apr. 9, 2015

(54) NOZZLE DESIGN FOR IMPROVED DISTRIBUTION OF REACTANTS FOR LARGE FORMAT SUBSTRATES

(71) Applicant: QUALCOMM MEMS TECHNOLOGIES, INC., San Diego, CA (US)

(72) Inventors: Ana R. Londergan, Santa Clara, CA (US); Sandeep K. Giri, Sunnyvale, CA (US); Teruo Sasagawa, Los Gatos, CA (US); Shih Chou Chiang, Taoyuan City (TW)

(73) Assignee: QUALCOMM MEMS TECHNOLOGIES, INC., San Diego, CA (US)

(21) Appl. No.: 14/045,716

(22) Filed: Oct. 3, 2013

(51) Int. Cl. H01L 21/67; H01L 21/285

(52) U.S. Cl. CPC H01L 21/67017; H01L 21/28556
USPC 438/680; 118/715

(57) ABSTRACT

Systems, methods and apparatus for processing a substrate are disclosed. A reactor for processing a substrate includes a reaction chamber, a substrate support, a nozzle, and an outlet. The chamber is configured to process a single substrate on the substrate support. The nozzle extends along an axis of elongation along a side of the chamber. The nozzle includes a nozzle body forming an inner volume, an inlet providing fluid communication between a reactant source and the inner volume, and a plurality of holes spaced along the axis of elongation. The holes provide fluid communication between the inner volume of the nozzle body and the reaction chamber. The nozzle is configured such that fluid conductance through the holes increases with increasing distance from the inlet. The outlet is configured to allow flow from the nozzle through the reaction chamber to the outlet. The flow is parallel to a major surface of the substrate.

### TECHNICAL FIELD

This disclosure relates to equipment and methods for processing substrates.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can include microelectromechanical systems (MEMS) devices with structures having sizes ranging from about a micron to hundreds of microns or more, or nanoelectromechanical systems (NEMS) devices with structures having sizes smaller than a micron including, for example, sizes smaller than several hundred nanometers, or other scales. Electromechanical elements may be created using deposition, etching, lithography, and/or other micromachining processes that etch away parts of substrates and/or deposited material layers, or that add layers to form electrical and electromechanical devices. One type of EMS device is called an interferometric modulator (IMOD), or interferometric light modulator, which refers to a device that selectively absorbs and/or reflects light using the principles of optical interference. An IMOD display element may include a pair of conductive plates, one or both of which may be transparent and/or reflective, wholly or in part, and capable of relative motion upon application of an appropriate electrical signal. The position of one plate in relation to another can change the optical interference of light incident on the IMOD display element. IMOD-based display devices have a wide range of applications, and are anticipated to be used in improving existing products and creating new products, especially those with display capabilities.

The aforementioned electromechanical systems devices can be fabricated using various processing tools and systems. Conventional semiconductor fabrication equipment, such as atomic layer deposition (ALD) and chemical vapor deposition (CVD), have been adapted for fabricating display panels. However, new challenges are being found in obtaining the desired uniformity for large rectangular substrates often used to form displays. Such substrates can be employed for MEMS displays, such as the IMOD display technology described above, as well as other display technologies, such as LCD, LED, OLED, etc. Equipment designs optimized for smaller, radially symmetric substrates, such as silicon wafers, are not readily adapted to these larger substrates of different shapes.

### SUMMARY

The systems, methods and devices of this disclosure each have several innovative aspects, no single one of which is solely responsible for the desirable attributes disclosed herein.

One innovative aspect of the subject matter described in this disclosure can be implemented in a reactor for processing a substrate. The reactor includes a reaction chamber configured to process a single substrate. The reactor includes a substrate support configured to support a single substrate within the reaction chamber. The reactor includes a nozzle extending along an axis of elongation along a side of the reaction chamber. The nozzle includes a nozzle body forming an inner volume; an inlet providing fluid communication between a reactant source and the inner volume; and a plurality of holes spaced along the axis of elongation. The holes provide fluid communication between the inner volume of the nozzle body and the reaction chamber. The holes are structurally configured such that fluid conductance through the holes increases with increasing distance from the inlet. The reactor includes an outlet from the reaction chamber positioned and configured to allow flow from the nozzle through the reaction chamber to the outlet, wherein the flow is parallel to a major surface of the substrate.

In some implementations, the holes increase in cross-sectional area with increasing distance from the inlet to provide the increase in fluid conductance. In some implementations, the spacing between the holes decreases with increasing distance from the inlet to provide the increase in fluid conductance. In some implementations, each hole is extended along a hole axis to form a plurality of inner channels, wherein the volume of the inner channels decreases with increasing distance from the inlet to provide the increase in fluid conductance.

Another innovative aspect of the subject matter described in this disclosure can be implemented in a reactor for processing a substrate. The reactor includes a reaction chamber configured to process a single substrate having a surface. The reactor includes a means for supporting a substrate within the reaction chamber. The reactor includes a means for injecting a reactant into the reaction chamber parallel to the substrate surface. The reactant injecting means includes means for compensating for pressure drop to distribute reactant flow across the substrate uniformly.

In some implementations, the reactant injecting means includes an inlet and a nozzle tube, the pressure drop compensating means including a plurality of holes in the nozzle tube, wherein the plurality of holes increase in cross-sectional area with increasing distance from the inlet. In some implementations, the reactant injecting means includes an inlet and a nozzle tube, the pressure drop compensating means including a plurality of holes in the nozzle tube, wherein spacing between the plurality of holes decreases with increasing distance from the inlet. In some implementations, the reactant injecting means includes an inlet and a nozzle tube, the pressure drop compensating means including a plurality of holes in the nozzle tube, wherein the holes are extended along a hole axis to form a plurality of inner channels, wherein the volume of the inner channels decreases with increasing distance from the inlet.

Another innovative aspect of the subject matter described in this disclosure can be implemented in a method of processing a substrate in a single substrate reaction chamber. The method includes distributing a reactant from a nozzle inlet along a nozzle plenum elongated along an edge of the substrate. The method includes injecting reactant from openings along the elongated nozzle plenum into the reaction chamber. Injecting includes reducing flow resistance with greater opening distance from the nozzle inlet to compensate for pressure drop with greater distance from the nozzle inlet. The method includes flowing the reactant from the openings through the reaction chamber to a reaction chamber outlet, wherein the flow is parallel to a major surface of the substrate.

In some implementations, reducing flow resistance includes one or more of: providing openings that increase in cross-sectional area with greater opening distance from the nozzle inlet; providing openings that decrease in spacing with respect to each other with greater opening distance from the nozzle inlet; and providing openings that extend along a hole axis to form a plurality of inner channels, wherein the volume of the inner channels decreases with increasing distance from the inlet.

Details of one or more implementations of the subject matter described in this disclosure are set forth in the accompanying drawings and the description below. Although the examples provided in this disclosure are primarily described in terms of EMS and MEMS-based displays the concepts provided herein may apply to equipment and methods of manufacturing other types of displays such as liquid crystal displays, organic light-emitting diode (“OLED”) displays, and field emission displays. Additionally, the concepts provided herein may apply to other types of devices formed on substrates, such as semiconductor and integrated circuits. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 is a flow diagram illustrating a manufacturing process for an IMOD display or display element.

FIGS. 2A-2F are cross-sectional illustrations of various stages in a process of making an IMOD display or display element.

FIG. 3 is an example of a schematic plan view of a reactor for processing a substrate, in accordance with one implementation.

FIG. 4 is an example of a schematic plan view of reactor for processing a substrate, in accordance with another implementation.

FIGS. 5A-5C are each an example of a front elevational view of a nozzle for a reaction chamber, each in accordance with an implementation.

FIG. 5D is an example of a horizontal cross-sectional view of a nozzle for a reaction chamber, in accordance with another implementation.

FIG. 6 is an elevational front cross-sectional view of a reactor for processing a substrate with two nozzles, in accordance with an implementation.

FIG. 7 is an example of a system block diagram illustrating a reactor including a reaction chamber and a control system, in accordance with an implementation.

FIG. 8 is example of a flow diagram illustrating a method of processing a substrate, in accordance with an implementation.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in apparatuses, systems, and processes to fabricate any device, apparatus, or system, such as those configured to display an image, whether in motion (such as video) or stationary (such as still images), and whether textual, graphical or pictorial. More particularly, it is contemplated that the described implementations may be associated with fabrication of a variety of electronic devices such as, but not limited to, electromechanical systems (EMS) applications including microelectromechanic al systems (MEMS) applications, as well as non-EMS applications. The teachings herein also can be used in fabrication of non-display electronic devices. Thus, the teachings are not intended to be limited to the implementations depicted solely in the Figures, but instead have wide applicability as will be readily apparent to one having ordinary skill in the art.

A reactor for processing a substrate is disclosed that can be used to fabricate a device (e.g., a MEMS or integrated circuit device). The reactor can include a substrate support for supporting a substrate within a reaction chamber, and in some implementations, a single substrate. A nozzle extending along a side of the reaction chamber can introduce reactant from an inlet and through a plurality of holes spaced along a body of the nozzle. The holes can be configured such that fluid conductance through the holes increases, or fluid resistance decreases, with increasing distance from the inlet.

Particular implementations of the subject matter described in this disclosure can be implemented to realize one or more of the following potential advantages. Reducing back-pressure within a vapor reactant nozzle (e.g., to 0.5 to 5 Torr), can be advantageous for reducing particle generation for some processes, such as atomic layer deposition (ALD). However, reduced back-pressure can also reduce flow uniformity of reactant across the substrate, and this problem can be exacerbated as substrate sizes are scaled up. Such uniformity was not perceived as being an issue for a self-limiting, saturative process, such as ALD, but has become an issue with large-format substrates. While MEMS devices have traditionally been manufactured on small-format substrates, to increase throughput and reduce cost, it would be beneficial to manufacture MEMS devices on large-format substrates. To improve ALD for the fabrication of MEMS devices using large-format substrates will require improved flow uniformity of reactant across the length of the nozzle and the substrate. The distribution of conductance of holes along a nozzle, as described herein, compensates for this reduced uniformity in reactant distribution and pressure drops within the nozzles, by providing even lower resistance to flow from the nozzle holes with greater distance from the nozzle inlet. A reaction chamber nozzle with holes configured to increase conductance with increasing distance from the nozzle inlet can improve reactant uniformity, and compensate for pressure drop along the length of the nozzle. Since pressure drop along the length of the nozzle is likely to be greater for nozzles with greater lengths, the improvement described herein will be greater for longer nozzles compared to shorter nozzles.

Implementations can be applied, for example, to manufacturing display devices and/or EMS devices. An example of a suitable EMS or MEMS device or apparatus, to which the described implementations may apply, is a reflective display device. Reflective display devices can incorporate interferometric modulator (IMOD) display elements that can be implemented to selectively absorb and/or reflect light incident thereon using principles of optical interference. IMOD display elements can include a partial optical absorber, a reflector that is movable with respect to the absorber, and an optical resonant cavity defined between the absorber and the reflector. In some implementations, the reflector can be moved to two or more different positions, which can change the size of the optical resonant cavity and thereby affect the reflectance of the IMOD. The reflectance spectra of IMOD display elements can create fairly broad spectral bands that can be shifted across the visible wavelengths to generate different colors. The position of the spectral band can be adjusted by changing the thickness of the optical resonant cavity. One way of changing the optical resonant cavity is by changing the position of the reflector with respect to the absorber.

In some single substrate reactors, the reactant distribution systems (e.g., showerheads or other nozzles) tend to rely on a high back-pressure behind nozzle injectors to improve uniformity of reactant distribution, and to increase film growth speed (to avoid the reduction in throughput of a single wafer system). However, high back-pressure with nozzle injection can increase particle generation, and thus reduce film and deposition quality. For example, in atomic layer deposition, high back-pressure can cause some amount of residual reactant to continue bleeding into the reactor from the nozzle after the first reactant is pulsed, and even during the second reactant pulse. This can result in gas phase interaction between mutually reactive ALD reactants and particulate formation, which can reduce quality of the devices being manufactured. Clearing (e.g., purging) the nozzles of reactants between pulse steps can reduce this particle formation, but high back-pressure can lengthen the time it takes for such purging steps.

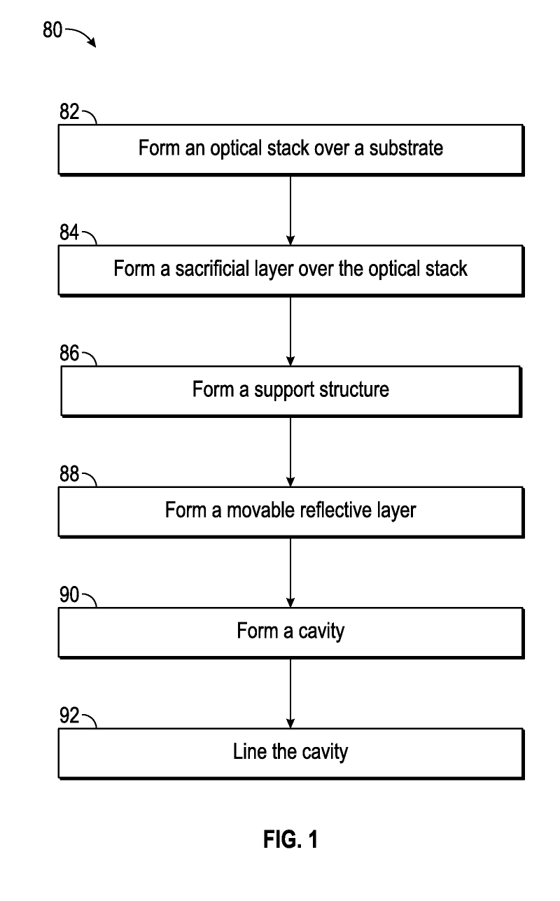

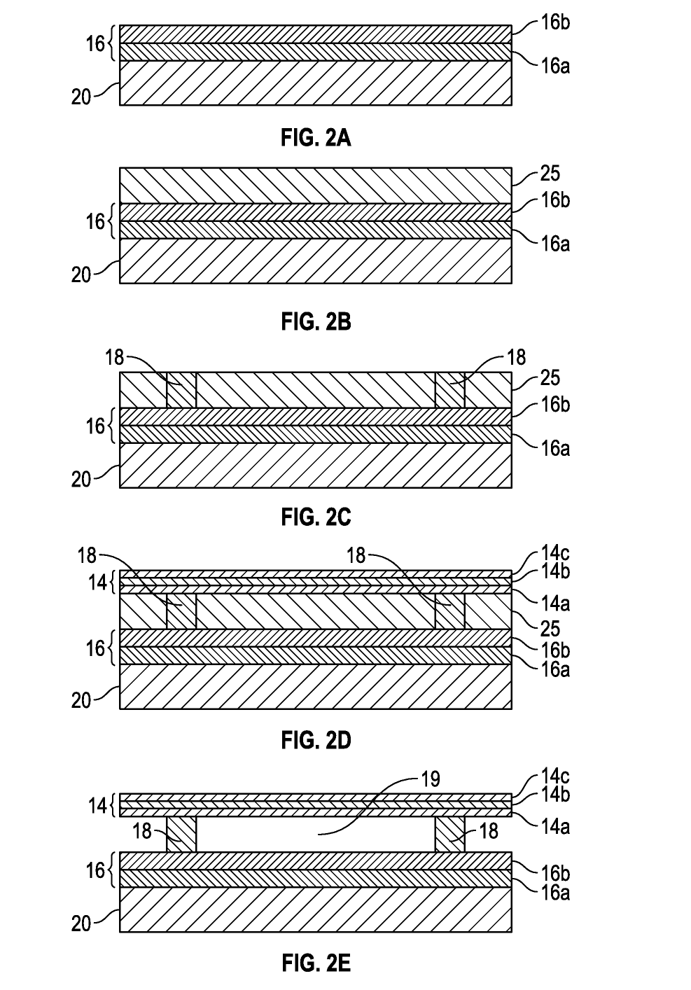

FIG. 1 is a flow diagram illustrating a manufacturing process 80 for an IMOD display or display element. FIGS. 2A-2F are cross-sectional illustrations of various stages in a manufacturing process 80 for making an IMOD display or display element. In some implementations, the manufacturing process 80 can be implemented to manufacture arrays of EMS devices, such as IMOD displays. The manufacture of such an EMS device also can omit some illustrated blocks and/or include other blocks not shown in FIG. 1. The process 80 begins at block 82 with the formation of an optical stack 16 over a substrate 20. FIG. 2A illustrates such an optical stack 16 formed over the substrate 20. The substrate 20 may be a substrate such as a glass substrate (sometimes referred to as a workpiece, glass plate or panel). Example substrates include standard rectangular formats, including G1 (˜300 mm×350 mm); G2 (˜370 mm×470 mm); G3 (˜550 mm×650 mm); G4 (˜730 mm×920 mm); G5 (˜1100 mm×1250 mm); G6 (˜1500 mm×1850 mm); G7 (˜1950 mm×2200 mm); G8 (˜2200 mm×2400 mm); G10 (2880 mm×3130 mm); In some implementations, the glass substrate may have a thickness of 0.3, 0.5 or 0.7 millimeters, although in some implementations the glass substrate can be thicker (such as tens of millimeters) or thinner (such as less than 0.3 millimeters).

The glass substrate may be or include, for example, aluminum silicate glass, a borosilicate glass, a soda lime glass, quartz, Pyrex, or other suitable glass material. In some implementations, a non-glass substrate can be used, such as a polyimide, polycarbonate, acrylic, polyethylene terephthalate (PET) or polyether ether ketone (PEEK) substrate. In such an implementation, the non-glass substrate will likely have a thickness of less than 0.7 millimeters, although the substrate may be thicker depending on the design considerations. In some implementations, a non-transparent substrate, such as a metal foil or stainless steel-based substrate can be used. In some implementations, the substrate may be or include silicon, or other materials used in IC manufacturing. The substrate 20 may be flexible or relatively stiff and unbending, and may have been subjected to prior preparation processes, such as cleaning, to facilitate efficient formation of the optical stack 16. The optical stack 16 can include an electrically conductive layer, and can be partially transparent, partially reflective and partially absorptive, and may be fabricated, for example, by depositing one or more layers having the desired properties onto the transparent substrate 20.

In FIG. 2A, the optical stack 16 includes a multilayer structure having sub-layers 16a and 16b, although more or fewer sub-layers may be included in some other implementations. In some implementations, one of the sub-layers 16a and 16b can be configured with both optically absorptive and electrically conductive properties, such as a combined conductor/absorber sub-layer 16a. In some implementations, one of the sub-layers 16a and 16b can include a semireflective thickness of a metallic material, such as molybdenum-chromium (molychrome or MoCr), or other materials with a suitable complex refractive index. Additionally, one or more of the sub-layers 16a and 16b can be patterned into parallel strips, and may form row electrodes in a display device. Such patterning can be performed by a masking and etching process or another suitable process known in the art. In some implementations, one of the sub-layers 16a and 16b can be an insulating or dielectric layer, such as an upper sub-layer 16b that is deposited over one or more underlying metal and/or oxide layers (such as one or more reflective and/or conductive layers). In addition, the optical stack 16 can be patterned into individual and parallel strips that form row electrodes of the display. In some implementations, at least one of the sub-layers of the optical stack, such as the optically absorptive layer, may be quite thin (for example, relative to other layers depicted in this disclosure), even though the sub-layers 16a and 16b are shown somewhat thick in FIGS. 2A-2F.

The process 80 continues at block 84 with the formation of a sacrificial layer 25 over the optical stack 16. Because the sacrificial layer 25 is later removed (see block 90) to form a cavity 19 (see FIG. 2E), the sacrificial layer 25 is not present in the resulting IMOD display elements. FIG. 2B illustrates a partially fabricated device including a sacrificial layer 25 formed over the optical stack 16. The formation of the sacrificial layer 25 over the optical stack 16 may include deposition of a fluorine-etchable material such as molybdenum (Mo) or amorphous silicon (Si), in a thickness selected to provide, after subsequent removal, a gap or cavity 19 (see FIG. 2E) having a desired design size. Deposition of the sacrificial material may be carried out using deposition techniques such as physical vapor deposition (PVD, which includes many different techniques, such as sputtering), plasma-enhanced chemical vapor deposition (PECVD), thermal chemical vapor deposition (thermal CVD), or spin-coating.

The process 80 continues at block 86 with the formation of a support structure such as a support post 18. The formation of the support post 18 may include patterning the sacrificial layer 25 to form a support structure aperture, then depositing a material (such as a polymer or an inorganic material, like silicon oxide) into the aperture to form the support post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the support post 18 contacts the substrate 20. Alternatively, as depicted in FIG. 2C, the aperture formed in the sacrificial layer 25 can extend through the sacrificial layer 25, but not through the optical stack 16. For example, FIG. 2E illustrates the lower ends of the support posts 18 in contact with an upper surface of the optical stack 16. The support post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 2C, but also can extend at least partially over a portion of the sacrificial layer 25. Patterning can include photolithography to mask the post regions with mask features slightly wider than the apertures, and a selective etch process designed to stop on the sacrificial layer 25. As noted above, the patterning of the sacrificial layer 25 and/or the support posts 18 can be performed by a masking and etching process, but also may be performed by alternative patterning methods. Such patterning and its selective etching processes are examples of processes that may be performed with implementations of the plasma apparatus and methods described further herein.

The process 80 continues at block 88 with the formation of a movable reflective layer or membrane such as the movable reflective layer 14 illustrated in FIG. 2D. The movable reflective layer 14 may be formed by employing one or more deposition steps, including, for example, reflective layer (such as aluminum, aluminum alloy, or other reflective materials) deposition, along with one or more patterning, masking and/or etching steps. The movable reflective layer 14 can be patterned into individual and parallel strips that form, for example, column electrodes of the display that cross with the row electrode strips formed from the optical stack 16. The movable reflective layer 14 can be electrically conductive, and referred to as an electrically conductive layer. In some implementations, the movable reflective layer 14 may include a plurality of sub-layers 14a, 14b and 14c as shown in FIG. 2D. In some implementations, one or more of the sub-layers, such as sub-layers 14a and 14c, may include highly reflective sub-layers selected for their optical properties, and another sub-layer 14b may include a mechanical sub-layer selected for its mechanical properties. In some implementations, the mechanical sub-layer may include a dielectric material. Since the sacrificial layer 25 is still present in the partially fabricated IMOD display element formed at block 88, the movable reflective layer 14 is typically not movable at this stage. A partially fabricated IMOD display element that contains a sacrificial layer 25 also may be referred to herein as an “unreleased” IMOD.

The process 80 continues at block 90 with the formation of a cavity such as the cavity 19 of FIG. 2E. The cavity 19 (FIG. 2E) may be formed by exposing the sacrificial material 25 (deposited at block 84) to an etchant. For example, an etchable sacrificial material such as Mo or amorphous Si may be removed by dry chemical etching by exposing the sacrificial layer 25 to a gaseous or vaporous etchant, such as vapors derived from solid XeF₂ for a period of time that is effective to remove the desired amount of material. The sacrificial material is typically selectively removed relative to the structures surrounding the cavity 19. Other etching methods, such as wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD display element may be referred to herein as a “released” IMOD.

The process 80 continues at block 92 with the lining of the cavity 19 with one or more layers as shown in FIG. 2F. For example, after release etching defines the cavity 19, at least the reflective layer 14a and top of the optical stack 16, and in the illustrated implementation all interior surfaces of the cavity 19, can be coated conformally with an antistiction layer 31. The illustrated conformal antistiction layer 31 includes a conformal layer 31a, which can be formed by atomic layer deposition (ALD), and a self-assembled monolayer (SAM) 31b as described below. In some implementations the conformal layer 31a can be an inorganic layer. In some implementations the conformal layer 31a can be a dielectric layer. It will be understood that antistiction properties can be obtained with one or both of the conformal layer 31a (formed, for example, by ALD) and the SAM 31b. For implementations in which both are employed, the conformal layer 31a can serve as a seed layer for forming the SAM thereover.

In some implementations, the packaging of a display, such as the IMOD-based display described above, can include a backplate (alternatively referred to as a backplane, back glass or recessed glass) which can be configured to protect the EMS components from damage (such as from mechanical interference or potentially damaging substances). The backplate also can provide structural support for a wide range of components, including but not limited to driver circuitry, processors, memory, interconnect arrays, vapor barriers, product housing, and the like. In some implementations, the use of a backplate can facilitate integration of components and thereby reduce the volume, weight, and/or manufacturing costs of a portable electronic device.

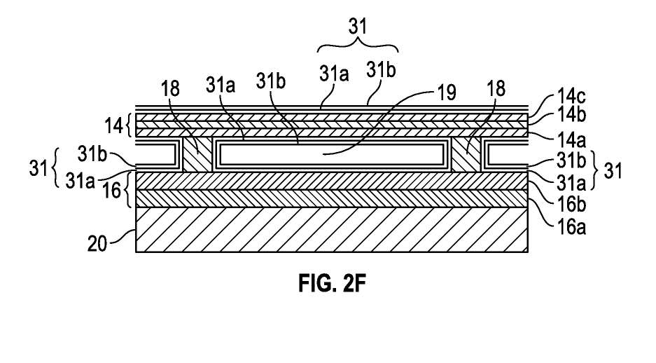

FIG. 3 is an example of a schematic plan view of a reactor for processing a substrate, in accordance with one implementation. A reactor 100 can include a reaction chamber 110 and a substrate support 120 configured (sized and shaped) to support a single workpiece or substrate 130 within the reaction chamber 110. For example, reaction chamber 110 and substrate support 120 can be configured sufficiently small enough such that only a single substrate can be processed therein, without use of a wafer boat or multiple-wafer substrate support. The reactor 100 can include a nozzle 140 configured to fluidly communicate one or more gases from gas storage or generation equipment to the reaction chamber 110. For example, the nozzle 140 can be configured to be in fluid communication with a reactant source 150. The nozzle 140 is configured to receive a reactant from the reactant source 150 and supply the reactant into the reaction chamber 110, to perform a process on the substrate 130.

In some implementations, reactor 100 can be configured for processes that use mixed reactants, such as CVD. Some CVD process use only one precursor, and so only one nozzle as described herein might be employed, e.g., depositing silane to form amorphous Silicon. Some CVD processes may include at least two reactants that are substantially non-reactive at the temperature of the composite nozzle (e.g., room temperature). Such processes can allow the at least two reactants to be mixed within a common gas line prior to entering the nozzle, and thus may be implemented with only one nozzle. Such processes may react the different reactants of the mixture at the higher temperature of the substrate, and/or react in the presence of a plasma inside the chamber.

Some CVD processes may include two or more reactants that are reactive within one another even at lower temperatures (such as room temperature). Such processes may include a first nozzle configured to inject a first reactant continuously during the deposition step, while a second nozzle injects a second reactant continuously. In some such CVD processes, a first nozzle may inject a first reactant through a first nozzle continuously during the deposition step, while a second nozzle pulses a second reactant. In some CVD processes, multi-component films may be deposited that could be provided with more than two nozzles and more than two reactants, such as a three reactant/nozzle configuration to deposit an indium tin oxide film (mix of indium oxide and tin oxide), or even three or four nozzles for indium gallium zinc oxide (depending on how oxygen is introduced into the process). With an ALD process, a first reactant is pulsed through one or more nozzles, followed sequentially by a pulse of a second reactant through one or more nozzles.

In some implementations, reactor 100 can be configured for ALD. With an ALD process, a first reactant is pulsed through a first nozzle, followed sequentially by a pulse of a second reactant through a second nozzle. A gas control system, such as a gas panel, valving and/or other components for controlling fluid flow, can be included between the reactant source 150 and the nozzle 140 to control the flow of gases into nozzle 140 and/or other portions of reactor 100.

In some implementations, reactor 100 and the other reactors described herein can include two or more nozzles configured to fluidly communicate one or more gases to a reaction chamber. For example, two or more nozzles may be implemented to separately provide two or more reactants into a reaction chamber, either sequentially, or simultaneously. The nozzle 140 can be in communication with one or more inert gas sources. For example, one or more inert gas sources can be configured to provide purge gas, or to act as a carrier for precursor, to the reaction chamber 110. Separate reactant sources with two or more separate nozzles may be employed to minimize risk of interaction of the reactants in the nozzle, such as residual first reactant from a first reactant pulse interacting with a subsequent second reactant pulse, thus minimizing risk of particulate generation from such interaction. For example, the reactant sources may include a vessel and/or vaporizer holding a metal reactant, such as trimethyl aluminum (TMA, (CH₃)₃Al) and another vessel and/or vaporizer for an oxygen source vapor, such as water, for the ALD deposition of aluminum oxide.

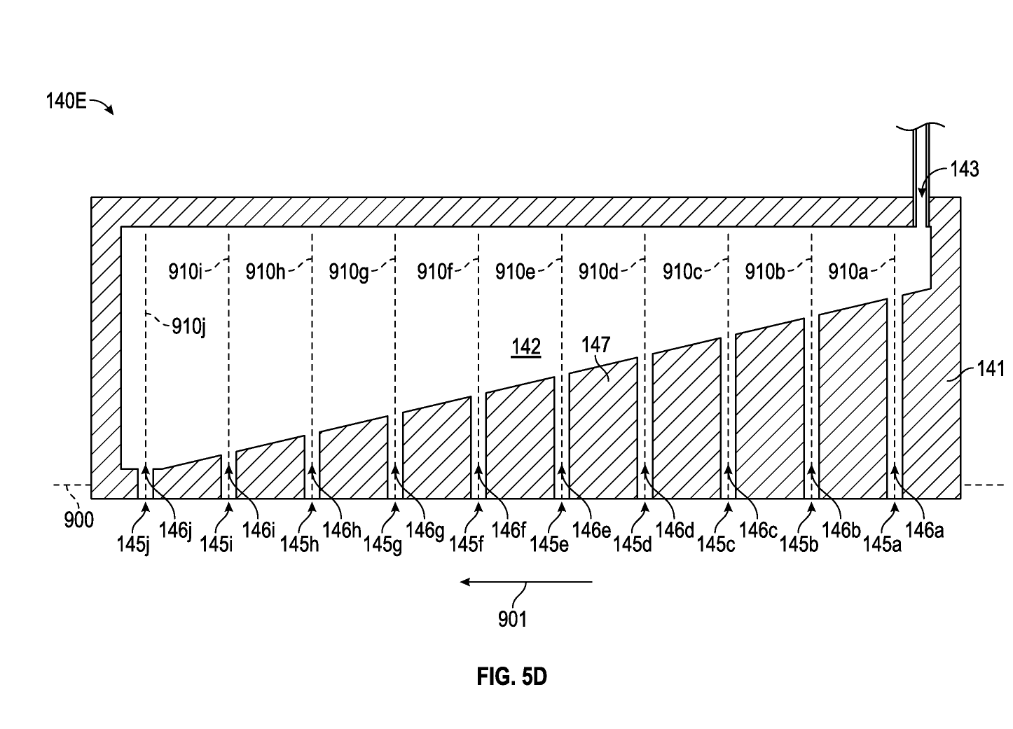

In operation, the TMA and water can be delivered to the reaction space by alternate and sequential pulses by high speed valves, with intervening removal of reactants from the nozzles and the reaction chamber, such as by providing an inert gas to purge the nozzles and reactor of the previous reactant. Removal of a first reactant from a first composite nozzle while a second reactant is supplied through a second composite nozzle reduces the risk of out-diffusion of the first reactant from the first composite nozzle while the second reactant is being supplied to the reaction chamber. As TMA is naturally liquid, the vessel can also serve as a vaporizer, such as a bubbler. The TMA can adsorb on surfaces of the batch of substrates in one reactant pulse, including inside the MEMS cavities in some implementations, and the water can react with the adsorbed species in a subsequent pulse to form a self-limited monolayer of aluminum oxide. Multiple cycles can be performed to form an aluminum oxide layer having a desired thickness, depending upon the average thickness per cycle (for example, from 0.5 Å/cycle to 10 Å/cycle). In some implementations, the aluminum oxide layer has a thickness of about 3 Å to about 50 Å. In some implementations, the aluminum oxide layer has a thickness of about 40 Å to about 90 Å. An example of an implementation of a reactor with two nozzles corresponding with two reactant sources is described further herein with reference to FIG. 6.

Continuing to refer to FIG. 3, the reactor 100 can include an outlet 160 configured to allow flow from the nozzle 140 through the reaction chamber 110, and to the outlet 160. The outlet 160 can include any of a number of different shapes suitable to exhaust the reaction chamber 110, such as one or more conduits, slots, openings, manifolds, etc. The outlet 160 can be configured to allow flow from the reaction chamber 110, for example, to allow continuous flow of reactant through the chamber during deposition and to purge the reaction chamber 110 after deposition or between ALD pulses through an exhaust system. The exhaust system can include any of a number of different components suitable to provide and/or control such exhaust, such as one or more vacuum pumps, valves, regulators, sensors (e.g., pressure sensors, temperature sensors, flow sensors, etc.), and other components, or combinations thereof. In general, the outlet 160 is positioned and its opening(s) are distributed on the opposite side of the reaction chamber 110 from the nozzle 140 such as to provide horizontal, laminar flow across the substrate support 120. For implementations in which nozzles are provided on multiple sides of the reaction chamber, multiple exhausts can be provided opposite each nozzle to provide a cross-flow path across the substrate.

The substrate 130 can be held or supported by the substrate support 120 using any of a number of different structures. The substrate support 120 can be configured to reduce contact between the substrate 130 and substrate support 120 to reduce contamination and/or damage to the substrate 130. For example, substrate support 120 may include an edge-grip susceptor, a recessed (concave) susceptor, and/or a plurality of support pins.

The reaction chamber 110 can be configured to receive substrates used to form electromechanical system devices and/or integrated circuit devices, such as glass, silicon, and the like. In an implementation, the reaction chamber 110 can be configured to process a rectangular glass substrate 130 ranging from an industry-standard display panel size G1 (300×350 mm) to G10 (2880×3130 mm). The reaction chamber 110 can process a substrate with a length that can range from about 350 mm to about 3130 mm, in one implementation; from about 470 mm to about 1850 mm, or from about 650 mm to about 1250 mm in another implementation. The reaction chamber 110 can process a substrate with a width that can range from about 300 mm to about 2880 mm in one implementation; from about 370 mm to about 1500 mm in another implementation; or from about 550 mm to about 1100 mm in another implementation. In one example, the substrate 130 can be a rectangular glass workpiece with a length×width of about 920 mm×730 mm. In some implementations, the reaction chamber 110 can be configured to process a substrate with dimensions that are greater than or equal to an industry-standard display panel size of G4, for example, between or including the industry-standard display sizes of G4 and G10. The reaction chamber can be configured to accommodate rectangular substrates with an area greater than about 700 mm by 900 mm.

The reaction chamber 110 can include sidewalls 111-114, a base 115, and a top (such as top 116, shown in the implementation of FIG. 6). The side(s), base(s), and top(s) of the reaction chambers described herein form an interior volume. In some implementations, sidewalls 111 and 113 can be positioned on approximately opposed sides of the substrate 130 with respect to each other, when the substrate 130 is positioned on the substrate support 120. In some implementations, sidewalls 112 and 114 can be positioned on approximately opposed sides of the substrate 130 with respect to each other, when the substrate 130 is positioned on the substrate support 120. Sidewall 112 and 114 can be adjacent and oriented orthogonally with respect to sidewalls 111 and 113.

The chamber 110 can include materials suitable for a substrate process, such as ALD and CVD. For example, the chamber 110 can include a metal and/or metal alloy such as aluminum, stainless steel, etc. Portions of the chamber exposed to reactants can be formed of a material resistant to the processing gas, to reduce corrosion that may be caused by the process. For example, in some implementations wherein the reactor 100 is configured as an ALD reactor, some portions of the reaction chamber 110 (within the ALD reaction space) can be made of a material that is resistant to TMA, water, reaction by-products and any cleaning etchants. Examples of suitable chamber materials include aluminum, aluminum alloy, anodized aluminum, SS304, SS316, quartz, or titanium and/or aluminum oxide. The surface of these materials may be treated, for example, through coatings (e.g., aluminum oxide or yttrium oxide), anodization or roughening (e.g., to prevent film peeling). The roughness can be 3 μm Ra. In some implementations the reaction space is periodically cleaned to remove aluminum oxide formed on the reaction space surfaces.

The reaction chamber 110 can be suitably configured to be sealed apart from the metered inlets and outlets, and held to a particular pressure during at least a portion of the process therein. In some implementations wherein the reactor 100 is configured as an ALD reactor, the pressure in the reaction space during the ALD process is from about 100 mTorr to about 1 Torr. Some implementations of the nozzles described herein can be applied within processes, such as ALD, with a low back-pressure of about 0.1 to 10 Torr, or in some implementations, 0.1 to 5 Torr, or in some implementations, 0.1 to 2 Torr. The back-pressure is defined as the difference between the pressure in the reaction space and the pressure inside the nozzle.

The nozzle 140 and outlet 160 can be positioned relative to each other to provide different flow paths of fluid across the substrate 130 when the substrate 130 is positioned on the substrate support 120. For example, the nozzle 140 can extend along an axis of elongation 900, such as along the side 111 of the reaction chamber 110 as shown. The axis of elongation 900 can be approximately parallel with an edge of the substrate 130 positioned on the substrate support 120. The axis of elongation 900 can be approximately horizontal. The nozzle 140 and the axis of elongation 900 can be positioned within the reaction chamber 110 to extend along the length or width of a substrate positioned on the substrate support 120. As illustrated in FIG. 3, the nozzle 140 and the axis of elongation 900 are oriented to extend along the longer dimension (e.g., length) of a substrate within reaction chamber 110, however it is understood that that the substrate 130 and the substrate support 120 can be oriented so that the shorter of the width of the nozzle 140 and the length of the nozzle 140 extends along the nozzle 140 axis of elongation 900.

The outlet 160 can be positioned such that flow through the reaction chamber 110 from the nozzle 140 to the outlet 160 can be approximately parallel to a major surface (such as the upper and/or lower surface) of the substrate 130, when the substrate 130 is positioned on the substrate support 120. Such flow that is parallel to a major surface of the substrate 130 can also be defined as “horizontal flow” or “cross-flow,” such that the reaction chamber 110 can be defined as a “horizontal flow” or “cross-flow” reaction chamber, or reactor 100 can be defined as a “horizontal flow” reactor or “cross-flow” reactor.

It will be understood that various positioning and quantities of nozzle(s) and outlet(s) can be implemented, for example, to achieve the horizontal or cross-flow within the reaction chambers described herein. Continuing to refer to FIG. 3, the nozzle 140 is shown as positioned on the side 111 of the reaction chamber 110 that is opposite to that of side 113, on which the outlet 160 is positioned. One or more additional nozzles and outlets (not shown) can be implemented, such that the nozzle 140 and outlet 160 shown in FIG. 3 can form a first nozzle and a first outlet. For example, a second nozzle can be positioned on a second side of the reaction chamber adjacent to the first nozzle (such as one of side 112 or 114 shown in FIG. 3), with a second, corresponding outlet on the opposite side of the reaction chamber relative to the second nozzle (such as the other of side 112 and 114). In some implementations, a second nozzle can be positioned on the same side of the reaction chamber as the first outlet (such as side 113 shown in FIG. 3), with a corresponding second outlet positioned on the opposite side of the reaction chamber as the second nozzle, or the same side as the first nozzle (such as side 111 shown in FIG. 3). In some implementations, such as that shown in FIG. 6, a first and second nozzle can be configured to extend along a common side of the reaction chamber.

The nozzle 140 can be configured in any of a number of different ways suitable to provide fluid communication between the reactant source 150 and the inner volume of the reaction chamber 110. The nozzle 140 can include any materials suitable for exposure to the process within reaction chamber 110, such as those materials described generally herein for reaction chamber 110, or other suitable materials. The nozzle 140 can include a nozzle body 141 forming an inner plenum or volume 142. The nozzle body 141 and inner volume 142 can be any of a number of different suitable shapes, and can be the same or different shape with respect to each other. The nozzle body 141 and inner volume 142 can form a nozzle tube of an approximately circular, square, or other cross-sectional shape.

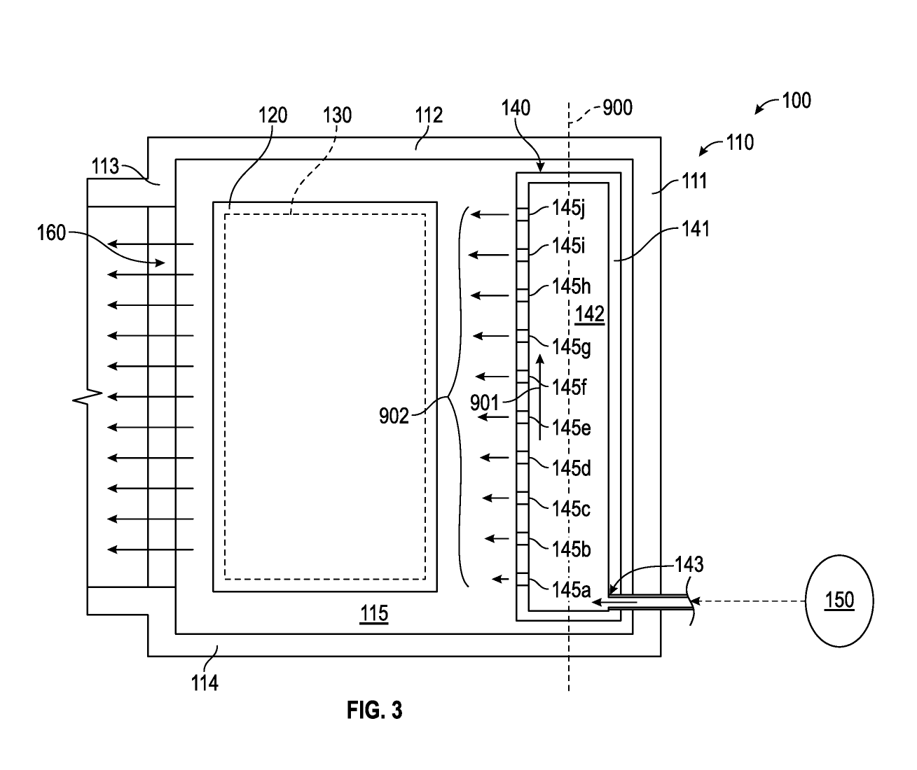

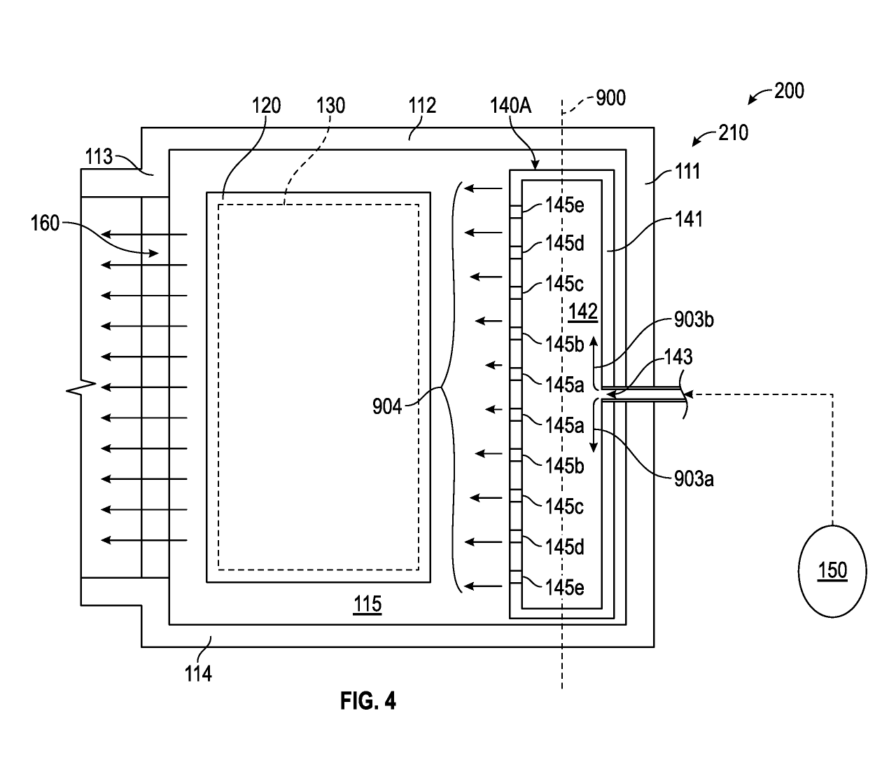

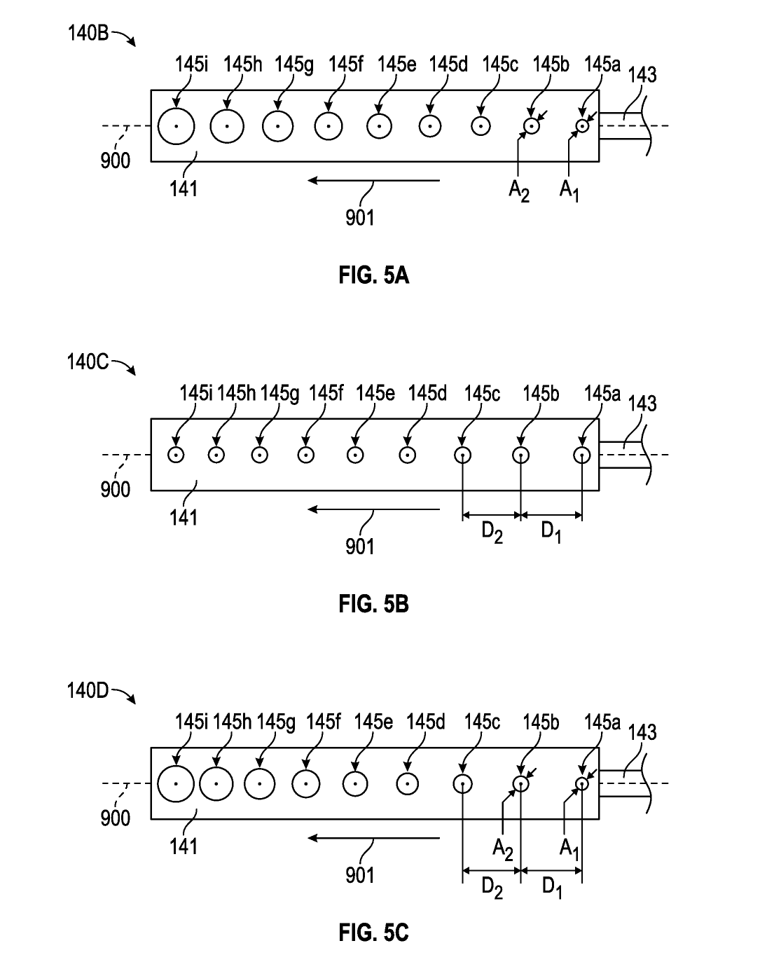

The nozzle 140 can include an inlet 143 configured to provide fluid communication between the reactant source 150 and the inner volume 142. The inlet 143 can include an opening, pipe, conduit, fitting, and/or other components suitable to provide this communication between the reactant source 150 and the inner volume 142. The inlet can be connected to an end portion of the nozzle body 141, as shown, or a more central portion of the nozzle body 141 (see FIG. 4). The inlet 143 can be oriented at different orientations relative to axis 900 and the body 141. For example, the inlet 143 can be oriented at an angle (e.g., approximately orthogonal) with respect to axis 900, as shown (see also FIG. 5D) or approximately parallel to (e.g., aligned with) axis 900 (FIGS. 5A-5C; FIG. 6). The inlet 143 can extend through and be connected to various portions of body 141, such as any of its sides, top or bottom, to provide fluid communication with the inner volume 142. In some implementations, the inlet 143 can extend through a portion of the reaction chamber 110, such as side 111, to communicate with the reactant source 150. Alternatively, the inlet 143 can be connected to a conduit or other fluid communication structure that extends through a portion of the reaction chamber 110.

A plurality of holes 145a-145j can be spaced along the axis of elongation 900. The holes 145a-145j can be positioned along axis 900 with increasing distance from the inlet 143, indicated by directional arrow 901. The holes can provide fluid communication between the inner volume 142 of the nozzle body 141 and the reaction chamber 110, and can have any suitable shape for providing such functionality. For example, the holes 145a-145j can have a curved cross-sectional shape, such as a round cross sectional shape, or can include flat portions, for example, to form a slot. It will be understood that the number of holes implemented within any of the nozzles described herein can be varied, and that the number of holes shown is for illustrative purposes only. For example, for a large, rectangular format substrate with dimensions of approximately 730 mm×920 mm, the number of holes in nozzle 140 may range between approximately 15 and 125, with a diameter that may range between approximately 0.2 mm and 1.25 mm.

The holes 145a-145j can be structurally configured such that fluid conductance through the holes 145a-145j increases (or flow resistance decreases) with increasing distance from the inlet 143. The increase in fluid conductance allows gas to flow more easily through holes 145a-145j with increasing distance from the inlet 143, as shown schematically by the increase in the lengths of the arrows 902. The increased flow conductance may compensate for a pressure drop with increasing distance from the inlet, and thus improve reactant flow uniformity across the substrate 130, as described further herein. Thus, the increase in the lengths of the arrows 902 represents increased flow conductance rather than flow rates. It will be understood in view of the disclosure herein that the compensating pressure drop only occurs for nozzles configured with relatively low back-pressure (i.e., relatively high overall flow conductance). The increased fluid conductance through holes 145a-145j with increasing distance from the inlet 143 can be provided through any of a number of different configurations.

FIG. 4 is an example of a schematic plan view of reactor 200 for processing a substrate, in accordance with another implementation. The reactor 200 can include many of the features described herein generally for a reactor for processing substrates such as reactor 100 (FIG. 3), and like reference numerals are employed for like parts. Reactor 200 can include a nozzle 140A that can allow the fluid conductance to increase with increasing distance from the inlet 143 of the nozzle 140A in two directions. For example, the inlet 143 of the nozzle 140A can be positioned to fluidly communicate with a middle portion of the nozzle body 141, rather than at one of the ends. Two sets of holes 145a-145e can extend along the longitudinal axis 900 outwardly in two directions 903a, 903b, respectively, from the inlet 143. Directions 903a, 903b can be opposite to each other; for example, directions 903a, 903b can be collinear. This implementation can allow the fluid conductance to increase (or flow resistance to decrease) with increasing distance from the inlet 143 in two directions, as shown by the increase in length of arrows 904 in two directions. Thus, the increase in the lengths of arrows 904 represents increased flow conductance rather than flow rates, similar to arrows 902 (FIG. 3). It will be understood that the positioning of the inlet 143 illustrated in FIG. 4 can be implemented with one or more of the various nozzle implementations shown in FIGS. 5A-6, and vice-versa.

FIGS. 5A-5C are each an example of a front elevational view of a nozzle for a reaction chamber, each in accordance with an implementation. FIG. 5D is an example of a horizontal cross-sectional view of a nozzle for a reaction chamber, in accordance with another implementation. FIGS. 5A-5D provide different examples of nozzles with different structural configurations of holes such that fluid conductance through the holes increases (or flow resistance decreases) with increasing distance from the nozzle inlet.

Referring to FIG. 5A, a nozzle 140B can include many of the features described herein generally for a nozzle for a cross-flow reaction chamber, such as nozzles 140 and 140A (FIGS. 3 and 4). The nozzle 140B can include the body 141, inlet 143, and a plurality of holes 145a-145i. The inlet 143 can be connected to an end portion of the nozzle body 141, and/or can be approximately parallel to axis 900. The cross sectional areas of holes 145a-145i can increase with increasing distance from the inlet 143 to provide an increase in fluid conductance. For example, hole 145b can comprise a cross sectional area A₂ that is greater than a cross sectional area A₁ of hole 145a. The increase in cross sectional area of hole 145b relative to hole 145a can be provided, for example, when holes 145a, 145b are approximately circular in cross-sectional shape, and hole 145b has a greater diameter than hole 145a. However, it will be understood that the increase in cross sectional area in the holes 145a-145i can be provided, for example, through various changes in shape and/or dimensions of holes 145a-145i with increasing distance from inlet 143. Additionally, while each progressive hole is shown larger than the prior hole in the simplified example of FIG. 5A, it will be understood that not every two adjacent holes need have different cross sectional areas with respect to each other to achieve an overall trend of increase in cross-sectional area of the holes and increase in fluid conductance (or decrease in fluid resistance) for the overall plurality of holes with increasing distance from the inlet. For example, the nozzle could be divided into two or more sections, with two or more holes in each section having the same area, but with the area of the holes increasing between sections of increasing distance from the inlet. Similar principles can be applied to include nozzle sections with the other implementations described herein that provide increased conductance with increased distance from the nozzle inlet, such as those with decreasing hole spacing (FIGS. 5B and 5C) and inner channels with increasing volume (FIG. 5D).

Referring to FIG. 5B, a nozzle 140C can include many of the features described herein generally for a nozzle for a cross-flow reaction chamber, such as nozzles 140-140B (FIGS. 3-5A). The nozzle 140C can include the body 141, inlet 143, and plurality of holes 145a-145h. The spacing between the holes can decrease with increasing distance from the inlet 143 to further provide an increase in fluid conductance (or decrease in flow resistance) with increasing distance from the inlet 143. For example, the spacing, or distance D1 between the centerlines of hole 145a and 145b, can be greater than the spacing, or distance D2, between the centerlines of hole 145b and 145c. While each progressive spacing is shown larger than the prior spacing in the simplified example of FIG. 5b, it will be understood that any two adjacent spacings need not be different with respect to each other to achieve an overall trend of decrease in spacings of the holes and corresponding increase in fluid conductance (or decrease in fluid resistance) for the overall plurality of holes with increasing distance from the inlet.

Referring to FIG. 5C, a nozzle 140D can include many of the features described herein generally for a nozzle for a cross-flow reaction chamber, such as nozzles 140-140C (FIGS. 3-5B). The nozzle 140D can include the body 141, inlet 143, and plurality of holes 145a-145g. In this implementation, both the spacing between the holes 140a-145g can decrease with increasing distance from the inlet 143, and the cross sectional areas of holes 145a-145g can increase with increasing distance from the inlet 143, to provide an increase in fluid conductance (or decrease in flow resistance) with increasing distance from the inlet 143, as described separately above with respect to FIGS. 5A and 5B.

Referring to FIG. 5D, a nozzle 140E can include many of the features described herein generally for a nozzle for a cross-flow reaction chamber, such as nozzles 140-140D (FIGS. 3-5C). The nozzle 140E can include the body 141, inlet 143, and plurality of holes 145a-145j. Holes 145a-145j can be similar or different cross-sectional size and shape with respect to each other. The plurality of holes 145a-145j can each be extended along corresponding hole axes 910a-910j, respectively, to form a plurality of inner channels 146a-146j, respectively. Hole axes 910a-910j can extend, for example, through a portion of body 141, such as a sidewall 147. Inner channels 146a-146j can be configured such that their volume can decrease with increasing distance from the inlet 143, to provide the increase in fluid conductance (or decrease in flow resistance) with increasing distance from the inlet 143. The volume of inner channels 146a-146j can be varied in any of many suitable ways. For example, the thickness of sidewall 147 can decrease along its length (in direction 901), which in turn can decrease the volume of inner channels 146a-146j and thus decrease their flow resistance. Alternatively or additionally, the volume of inner channels 146a-146j can be varied by varying the cross-sectional shape and/or size of holes 145a-145j. Alternatively or additionally, the volume of inner channels 146a-146j can be varied by including a pipe or conduit for each inner channel attached to sidewall 147, wherein the pipe or conduit has decreasing volume with increasing distance from the inlet 143. Use of such pipes or conduits can be implemented with a sidewall of constant thickness along the hole axes 910a-910j. It will be understood that the cross-sectional area and/or spacing of the holes in the implementation shown in FIG. 5D can be varied, similarly to those implementations shown in FIGS. 5A-5C, to further affect the fluid conductance with increasing distance from the inlet.

FIG. 6 is an elevational front cross-sectional view of a reactor for processing a substrate with two nozzles, in accordance with an implementation. It will be understood that two or more nozzles can be implemented within the various reactors described herein, unless stated otherwise. A reactor 300 can include a reaction chamber 310, and many of the features described herein generally for a reactor for processing substrates such as reactor 100 (FIG. 3) or reactor 200 (FIG. 4). Reactor 300 can include a first nozzle 340A in fluid communication with a first reactant source 150A through a first inlet 143A, and a separate second nozzle 340B in fluid communication with a different, second reactant source 150B through a second, separate inlet 143B. The nozzles 340A and 340B can include a plurality of holes 345a-345j and 346a-346i, extending along axes 900A and 900B, respectively, which are similar to those other nozzle openings described herein. The nozzles 340A and/or 340B can include any of the hole or channel configurations described herein for increasing fluid conductance with respect to increasing distance from inlets 143A and 143B. For example, although the holes 345a-345j are shown for illustrative purposes as having approximately the same size or spacing, it is understood that as discussed elsewhere, in some implementations, the holes 345a-345j can be structurally configured such that fluid conductance through the holes increases with increasing distance from an inlet into the nozzle from a reactant source, such as those implementations of FIGS. 5A-5D. Including two or more nozzles, such as nozzles 340A and 340B, can allow processes to be performed within the reaction chamber 310 that use two reactants where it is desirable to avoid common flow paths before entering the reaction space, such as ALD and/or some CVD processes.

The nozzles 340A and 340B can be stacked (e.g., vertically) with respect to each other, as shown. The stacked separate nozzles can allow a first gas, such as an inert gas or first reactant, to be flowed from one of the two nozzles, while a second gas, such as an inert gas or second reactant, is flowed from the other of the two nozzles. For example, an inert gas may be flowed from the lower nozzle 340B to mix, and thus improve uniformity of distribution, of a reactant flowing from nozzle 340A to substrate 130. For ALD typically one nozzle flows a reactant while the other nozzle flows an inert gas. Moreover, the openings of two nozzles that are vertically stacked can be staggered, as shown. Moreover, the openings of two nozzles that are vertically stacked can be staggered, as shown. Staggering the openings can help prevent vortices of reactants leaving the nozzles, which can cause increased, unwanted particle deposition. Whether or not staggered, the stacked arrangements provides particular uniformity benefits for the reactant flowed from the upper nozzle 140, which can ride on top of the inert gas flow below and thus better diffuse laterally before encountering the substrate. Such a configuration can provide increased improvements in uniformity of reactant distribution for a first reactant such as H₂O, flowed from the upper nozzle 340A, which would otherwise have decreased uniformity of distribution relative to a second reactant flowed from nozzle 340B (between nozzle 340A and the substrate), such as TMA. In the implementation shown in FIG. 6, the holes of nozzles 340A and 340B are offset or staggered with respect to each other and axes 900A, 900B.

In some implementations, two or more nozzles can be positioned on a common side of the reaction chamber 310 with respect to each other, such as nozzles 340A and 340B as shown in FIG. 6. In some implementations, the nozzles 340A and 340B can be positioned on different sides of the reaction chamber 310 with respect to each other, such as two adjacent sides, or two opposing sides.

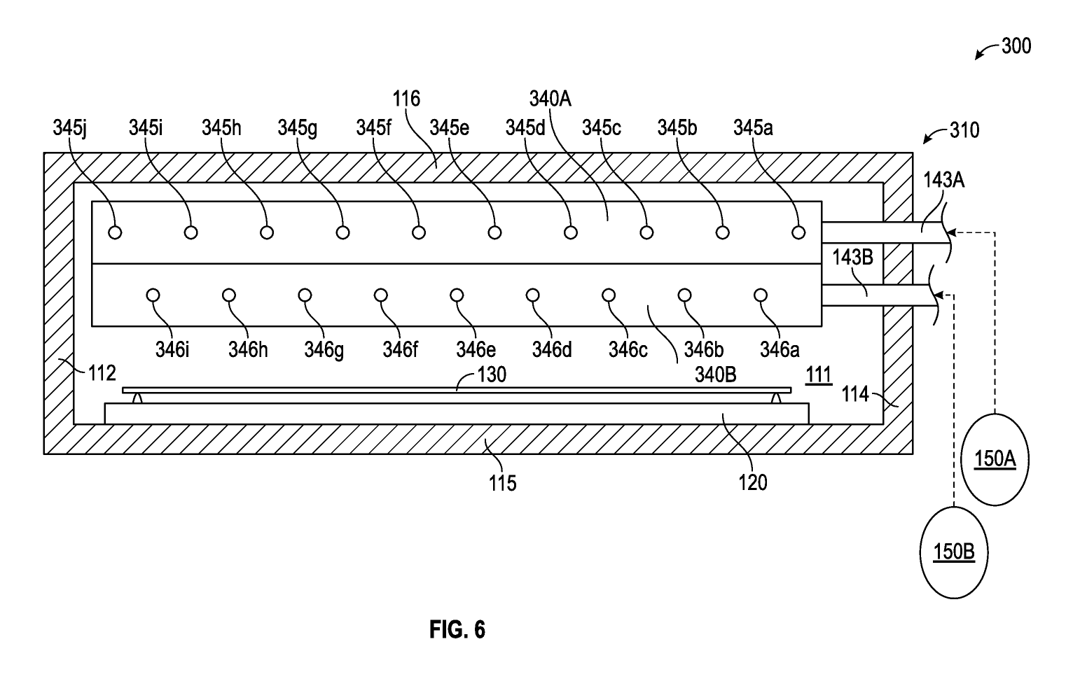

FIG. 7 is an example of a system block diagram illustrating the reactor 100 including a reaction chamber and a control system, in accordance with an implementation. Reactor 100 can include a control system or controller 1000 to control various features of, or methods provided by, one or more other components of the reactor 100, such as the reaction chamber 110. The reactor 100 can be controlled electronically, but can include other types of control sub-systems or components such as pneumatic or hydraulic. The control system 1000 can include any of a number of configurations, and can include any of a variety of controllers, user interfaces, buttons, switches, circuits, and the like. The control system 1000 can control any of the number of components of the reaction chamber 110. For example, the control system 1000 can control the flow of gas into or from the reaction chamber, or within portions of the reaction chamber. The control system 1000 can be configured to control different reactants into the reaction chamber. For example, control system 1000 can control valves to alternatingly switch between different reactant sources and outlets (if multiple outlets are positioned on different sides), and vacuum pump(s) to control system pressure, possible responsive to a feedback loop from a pressure sensor. The control system 1000 can control the robotics implementing movement of the substrate to and from the reaction chamber 110. In some implementations, the control system 1000 can be in communication with, and/or can be a part of, a control system and/or network within a facility for fabricating electromechanical system devices and/or integrated circuit devices.

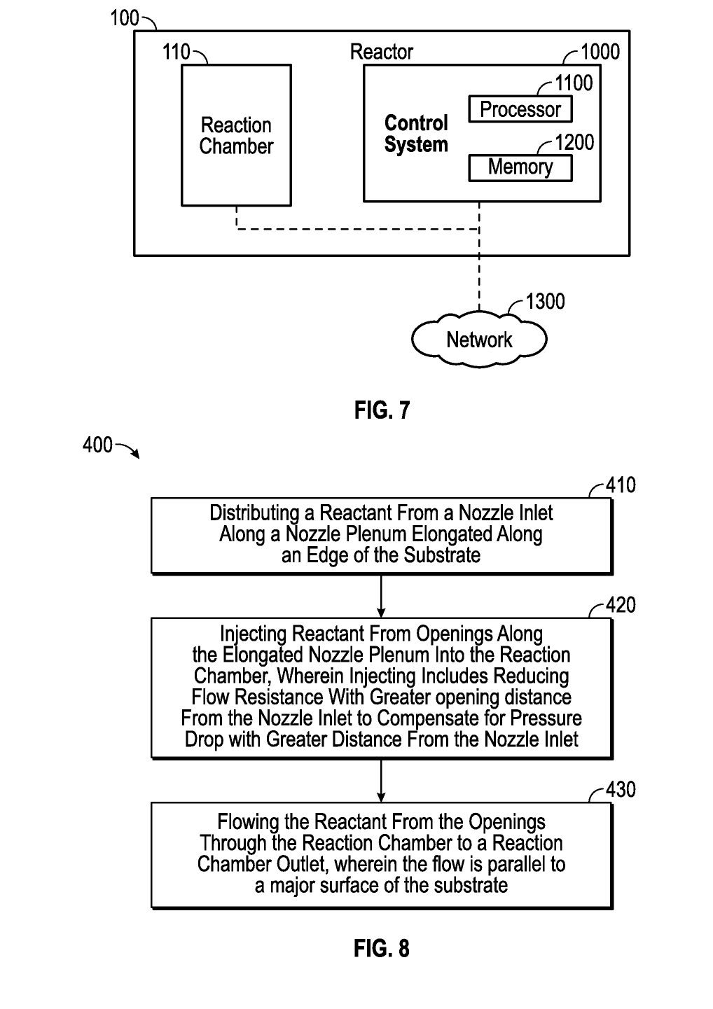

In some implementations, the control system 1000 can be hard-wired to the components or sub-components of reactor 100, or can be configured to control the components or sub-components wirelessly. The control system 1000 can be in communication with a network 1300. The control system 1000 can be attached to a portion of reactor 100 (for example, reaction chamber 110) or can be separate from such a portion of reactor 100. In some implementations, the control system 1000 can be configured to control various aspects of the reactor 100 remotely (e.g., through a telecommunication system, wirelessly, and/or an additional control system that sends a control signal to control system 1000, etc.), that allow remote interaction with and control one or more reactors 100 and their components, for example, from a central station. The control system 1000 can include a processor 1100, which can be a central processing unit (CPU), a microcontroller, or a logic unit. In some implementations, the control system 1000 can include a memory 1200, which can be local to the remainder of control system 1000, or can be located remote from the remainder of control system 1000 (for example, through cloud computing methods). The memory 1200 can include programming for conducting processing on substrates in sequence, including the method of FIG. 8, described below.

FIG. 8 is an example of a flow diagram illustrating a method 400 of processing a substrate, in accordance with an implementation. The method 400 can include distributing a reactant from a nozzle inlet along a nozzle plenum elongated along an edge of the substrate at block 410. At block 420, the method can include injecting reactant from openings along the elongated nozzle plenum into the reaction chamber. Injecting can include reducing flow resistance with greater opening distance from the nozzle inlet to compensate for pressure drop with greater distance from the nozzle inlet. At block 430, the method can include flowing the reactant from the openings through the reaction chamber to a reaction chamber outlet, wherein the flow is parallel to a major surface of the substrate.

In some implementations, reducing flow resistance includes one or more of providing openings that increase in cross-sectional area with greater opening distance from the nozzle inlet; providing openings that decrease in spacing with respect to each other with greater opening distance from the nozzle inlet; providing openings that extend along a hole axis to form a plurality of inner channels, wherein the volume of the inner channels decreases with increasing distance from the inlet; and combinations of such mechanisms for altering flow resistance. In some implementations, injecting reactant includes presenting a back-pressure of less than 5 Torr to gases. In some implementations, distributing the reactant includes providing a reactant to the nozzle inlet at a middle portion of the nozzle plenum, such that reducing flow resistance compensates for pressure drop with greater distance from the nozzle inlet in two directions. In some implementations, the method further includes repeating the method within the single substrate reaction chamber, with a separate reactant, on a separate nozzle inlet along a separate nozzle plenum, with separate openings. In some implementations, the method includes performing an ALD process. In some implementations, distributing the reactant from the nozzle inlet and distributing the separate reactant from the separate nozzle inlet includes distributing from a common edge of the substrate.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various methods described in connection with the implementations disclosed herein may be implemented manually or through automation controlled by electronic hardware, computer software, or combinations of both. Whether such functionality is implemented in hardware or software depends upon the particular application and design constraints imposed on the overall system.

For automated control, the hardware and data processing apparatus used to implement the functionability described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper,” “lower,” “horizontal,” “vertical,” “up,” “down,” “top,” “front,” bottom,” and “side” are sometimes used for ease and convenience of describing the figures, components, and views, and indicate relative positions corresponding to the orientation of the figure on a properly oriented page, and may not reflect the proper orientation of, for example, nozzles relative to the workpiece and/or outlet in some implementations. These terms should not limit the invention to any absolute orientations, for example, with respect to ground; the entire reactors described herein, could be oriented on its side, upside down, etc.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A reactor for processing a substrate, comprising:
a reaction chamber configured to process a single substrate;
a substrate support configured to support a single substrate within the reaction chamber;
a nozzle extending along an axis of elongation along a side of the reaction chamber, the nozzle including:
a nozzle body forming an inner volume;
an inlet providing fluid communication between a reactant source and the inner volume; and
a plurality of holes spaced along the axis of elongation, the holes providing fluid communication between the inner volume of the nozzle body and the reaction chamber, wherein the holes are structurally configured such that fluid conductance through the holes increases with increasing distance from the inlet; and
an outlet from the reaction chamber positioned and configured to allow flow from the nozzle through the reaction chamber to the outlet, wherein the flow is parallel to a major surface of the substrate.

2. The reactor of claim 1, wherein the holes increase in cross-sectional area with increasing distance from the inlet to provide the increase in fluid conductance.

3. The reactor of claim 2, wherein the spacing between the holes decreases with increasing distance from the inlet to further provide the increase in fluid conductance.

4. The reactor of claim 1, wherein the spacing between the holes decreases with increasing distance from the inlet to provide the increase in fluid conductance.

5. The reactor of claim 1, wherein each hole is extended along a hole axis to form a plurality of inner channels, wherein the volume of the inner channels decreases with increasing distance from the inlet to provide the increase in fluid conductance.

6. The reactor of claim 1, wherein the nozzle is configured to present a back-pressure of less than 5 Torr to gases.

7. The reactor of claim 1, wherein the inlet provides fluid communication to a middle portion of the nozzle body such that the fluid conductance increases with increasing distance from the inlet in two directions.

8. The reactor of claim 1, wherein the reactor is configured for chemical vapor deposition (CVD).

9. The reactor of claim 8, wherein the reactor includes separate ones of the nozzle for each CVD reactant, and a control system configured to continuously provide the first CVD reactant through the first nozzle while continuously or intermittently providing the second reactant through the second nozzle.

10. The reactor of claim 1, wherein the reactor is configured for atomic layer deposition (ALD), and includes separate ones of the nozzle, each nozzle in communication with a different ALD reactant source.

11. The reactor of claim 10, further including a control system for alternatingly switching between the different reactant sources.

12. The reactor of claim 10, wherein the separate ones of the nozzle extend along a common side of the reaction chamber.

13. The reactor of claim 12, wherein the separate ones of the nozzle includes a first nozzle and a second nozzle, wherein the plurality of holes of the first nozzle are staggered with respect to the plurality of holes of the second nozzle.

14. The reactor of claim 12, wherein the separate ones of the nozzle includes a first nozzle in fluid communication with an H₂O source, and a second nozzle in communication with a trimethyl aluminum (TMA) source, wherein the second nozzle is positioned between the first nozzle and the substrate support.

15. The reactor of claim 12, wherein the common side of the reaction chamber is positioned on an opposite side of the substrate support relative to the outlet.

16. The reactor of claim 1, wherein the reaction chamber is configured to process rectangular substrates having an area greater than or equal to the area of rectangular substrate with dimensions of about 700 mm×900 mm.

17. The reactor of claim 1, wherein the holes are structurally configured to increase the fluid conductance and compensate for pressure drop within the inner volume to more uniformly distribute reactant flow across the substrate compared to a nozzle having a uniform fluid conductance across the inner volume.

18. A reactor for processing a substrate, comprising:
a reaction chamber configured to process a single substrate having a surface;
a means for supporting a substrate within the reaction chamber;
a means for injecting a reactant into the reaction chamber parallel to the substrate surface, the reactant injecting means including means for compensating for pressure drop to distribute reactant flow across the substrate uniformly.

19. The reactor of claim 18, wherein the reactant injecting means includes an inlet and a nozzle tube, and wherein the pressure drop compensating means includes one or more of:
a plurality of holes that increase in cross-sectional area with increasing distance from the inlet;
a plurality of holes in which spacing between the plurality of holes decreases with increasing distance from the inlet; and
a plurality of holes that are extended along a hole axis to form a plurality of inner channels, wherein the volume of the inner channels decreases with increasing distance from the inlet.

20. The reactor of claim 18, wherein the reactant injecting means is configured to present a back-pressure of less than 5 Torr to gases.

21. The reactor of claim 18, wherein the reactant injecting means includes an inlet and a nozzle tube, the inlet connected to a middle portion of the nozzle tube, wherein the means for compensating for pressure drop is configured to increase the flow conductance out of the nozzle tube with increasing distance from the means for providing reactant in two directions.

22. The reactor of claim 18, wherein the reactor includes separate ones of the reactant injecting means, each reactant injecting means in communication with a different reactant source.

23. The reactor of claim 22, wherein the reactor is configured for atomic layer deposition (ALD), and includes separate ones of the reactant injecting means for each ALD reactant.

24. A method of processing a substrate in a single substrate reaction chamber, comprising:
distributing a reactant from a nozzle inlet along a nozzle plenum elongated along an edge of the substrate;
injecting reactant from openings along the elongated nozzle plenum into the reaction chamber, wherein injecting includes reducing flow resistance with greater opening distance from the nozzle inlet to compensate for pressure drop with greater distance from the nozzle inlet; and
flowing the reactant from the openings through the reaction chamber to a reaction chamber outlet, wherein the flow is parallel to a major surface of the substrate.

25. The method of claim 24, wherein reducing flow resistance includes one or more of:
providing openings that increase in cross-sectional area with greater opening distance from the nozzle inlet;
providing openings that decrease in spacing with respect to each other with greater opening distance from the nozzle inlet; and
providing openings that extend along a hole axis to form a plurality of inner channels, wherein the volume of the inner channels decreases with increasing distance from the inlet.

26. The method of claim 24, wherein injecting reactant includes presenting a back-pressure of less than 5 Torr to gases.

27. The method of claim 24, wherein distributing the reactant includes providing a reactant to the nozzle inlet at a middle portion of the nozzle plenum, such that reducing flow resistance compensates for pressure drop with greater distance from the nozzle inlet in two directions.

28. A method comprising repeating the method of claim 24 within the single substrate reaction chamber, with a separate reactant, on a separate nozzle inlet along a separate nozzle plenum, with separate openings.

29. The method of claim 28, wherein the method includes performing an ALD process.

30. The method of claim 28, wherein the distributing the reactant from the nozzle inlet and distributing the separate reactant from the separate nozzle inlet includes distributing from a common edge of the substrate.
